(19) United States
(12) Patent Application Publication
(10) Pub. No.: US 2026/0123187 A1
(43) Pub. Date: Apr. 30, 2026

(54) DISPLAY PANEL AND ELECTRONIC DEVICE

(71) Applicant: Hefei Visionox Technology Co., Ltd., Hefei (CN)

(72) Inventor: Zhiwei ZHOU, Hefei (CN)

(73) Assignee: Hefei Visionox Technology Co., Ltd., Hefei (CN)

(21) Appl. No.: 19/235,499

(22) Filed: Jun. 11, 2025

(30) Foreign Application Priority Data
Oct. 31, 2024 (CN) 202411555551.4

(51) Int. Cl. H10K 59/122; H10K 59/80

(52) U.S. Cl. CPC H10K 59/122; H10K 59/873

(57) ABSTRACT

Embodiments of the present application provide a display panel and an electronic device, which relate to the field of display. In the display panel, an isolation structure is located on a substrate and includes a plurality of isolation openings, and the plurality of isolation openings are arrayed in a plurality of columns of isolation openings arranged in a second direction, where a contour line of an orthographic projection of each isolation opening on the substrate includes a first contour line and a second contour line that extend in a first direction and are located on opposite sides of the isolation opening, and in the same column of isolation openings, the first contour lines of different isolation openings are flush and the second contour lines of different isolation openings are flush.

### CROSS-REFERENCE TO RELATED APPLICATIONS

The present application claims priority to the Chinese Patent Application No. 202411555551.4, filed on Oct. 31, 2024, and the entire contents of the aforementioned application are hereby incorporated by reference in its entirety

### FIELD

The present application relates to the field of display, and particularly to a display panel and an electronic device.

### BACKGROUND

Organic light emitting diode (OLED) is regarded as the next-generation display technology after liquid crystal display technology, which is widely applied in various consumer electronic products such as smart phones, televisions, laptop computers, desktop computers, vehicle-mounted displays and wearable devices due to its excellent color and image quality, and has become the mainstream technology in display panels.

However, the process performance of current OLED display products still needs to be further improved.

### SUMMARY

In order to overcome the problem mentioned in the above Background, the present application provides a display panel and an electronic device.

In a first aspect of the present application, a display panel is provided. The display panel includes:
a substrate;
an isolation structure located on the substrate and including a plurality of isolation openings, the plurality of isolation openings being arrayed in a plurality of columns of isolation openings arranged in a second direction, where
a contour line of an orthographic projection of each isolation opening on the substrate includes a first contour line extending in a first direction and located on a side of the isolation opening and a second contour line located on a side opposite the side where the first contour line is located and extending in the first direction; and in the same column of isolation openings, the first contour lines of different isolation openings are flush, and the second contour lines of different isolation openings are flush, the first direction intersecting the second direction;
light-emitting devices, at least part of the light-emitting devices being located in the isolation openings; and
encapsulation units for encapsulating the light-emitting devices in the isolation openings.

In a second aspect of the present application, a display panel is further provided. The display panel includes:
a substrate;
an isolation structure located on the substrate and including a plurality of isolation openings, the plurality of isolation openings being arrayed in a plurality of columns of isolation openings arranged in a second direction;
light-emitting devices, at least part of the light-emitting devices being located in the isolation openings; and
encapsulation units for encapsulating the light-emitting devices in the isolation openings, where a contour line of an orthographic projection of each encapsulation unit on the substrate includes a fifth contour line extending in a first direction and located on a side of the encapsulation unit and a sixth contour line located on a side opposite the side where the fifth contour line is located and extending in the first direction, the first direction intersecting the second direction; and
the fifth contour lines of different encapsulation units for encapsulating the light-emitting devices in different isolation openings in the same column of isolation openings are flush, and the sixth contour lines of different encapsulation units for encapsulating the light-emitting devices in different isolation openings in the same column of isolation openings are flush.

In a third aspect of the present application, an electronic device is further provided. The electronic device includes a display panel in any one of possible implementations in the first aspect or the second aspect.

Embodiments of the present application provide a display panel and an electronic device. In the display panel, an isolation structure is located on a substrate and includes a plurality of isolation openings, and the plurality of isolation openings are arrayed in a plurality of columns of isolation openings arranged in a second direction, where a contour line of an orthographic projection of each isolation opening on the substrate includes a first contour line and a second contour line that extend in a first direction and are located on opposite sides of the isolation opening, and in the same column of isolation openings, the first contour lines of different isolation openings are flush and the second contour lines of different isolation openings are flush. With such a design, when the isolation structure is laterally etched by an etching solution, a channel for fast flow of the etching solution is formed in the first direction, so as to avoid gathering or accumulation of the etching solution at some positions, so that the amount of lateral etching of the isolation structure at different positions is uniform, ensuring product quality and yield and improving display effect of the display panel.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope. Other related drawings can be obtained from these drawings.

FIG. 1 illustrates a schematic diagram of a position relationship between an isolation structure and isolation openings in a display panel according to an embodiment;

FIG. 2 illustrates a first schematic cross-sectional diagram of position AA in FIG. 1;

FIG. 3 illustrates a schematic diagram of distances between corresponding contour lines of the respective isolation openings in the display panel according to this embodiment;

FIGS. 4a, 4b and 4c illustrate schematic diagrams of different distributions of the isolation openings in the display panel according to this embodiment;

FIGS. 5a, 5b and 5c illustrate schematic diagrams of different distributions of encapsulation units and the isolation openings in the display panel according to this embodiment;

FIG. 6 illustrates a schematic diagram of distances between corresponding contour lines of the respective encapsulation units in the display panel according to this embodiment;

FIG. 7 illustrates a second schematic cross-sectional diagram of the position AA in FIG. 1;

FIGS. 8a, 8b and 8c illustrate schematic diagrams of different distributions of first electrodes and the isolation openings in the display panel according to this embodiment;

FIG. 9 illustrates a schematic diagram of distances between corresponding contour lines of the respective first electrodes in the display panel according to this embodiment;

FIG. 10 illustrates a schematic diagram of different distributions of pixel openings and the isolation openings in the display panel according to this embodiment;

FIG. 11 illustrates a schematic diagram of distances between corresponding contour lines of the respective pixel openings in the display panel according to this embodiment; and

FIG. 12 illustrates a third schematic cross-sectional diagram of the position AA in FIG. 1.

List of reference signs: 1—display panel; 11—substrate; 12-isolation structure; 1201—isolation opening; 1201a—first isolation opening; 1201b—second isolation opening; 1201c—third isolation opening; 1211—column of isolation openings; 1212—row of isolation openings; 121—first isolation part; 122—second isolation part; 13—light-emitting device; 13a—first light-emitting device; 13b—second light-emitting device; 13c—third light-emitting device; 131—first electrode; 131a—first sub-electrode; 131b—second sub-electrode; 131c—third sub-electrode; 1311—column of first electrodes; 1312—row of first electrodes; 132—light-emitting material layer; 133—second electrode; 141—encapsulation unit; 141a—first encapsulation unit; 141b—second encapsulation unit; 141c—third encapsulation unit; 142—first encapsulation layer; 143—second encapsulation layer; 15—pixel defining layer; 1501—pixel opening; 1501a—first pixel opening; 1501b—second pixel opening; 1501c—third pixel opening; 15011—column of pixel openings; 15012—row of pixel openings; 201—first contour line; 202—second contour line; 203—third contour line; 204—fourth contour line; 205—fifth contour line; 206—sixth contour line; 207—seventh contour line; 208—eighth contour line; 209—ninth contour line; 210—tenth contour line; 211—eleventh contour line; 212—twelfth contour line; 213—thirteenth contour line; 214—fourteenth contour line.

### DETAILED DESCRIPTION OF THE EMBODIMENTS

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

In the description of the present application, it should be noted that orientations or position relationships indicated by terms such as “upper” and “lower” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application.

Increasing the density (i.e. pixel density) of light-emitting devices in a display panel is an important way to improve the display effect. However, display panels currently made by using the fine metal mask (FMM) technology are unable to further increase the density of light-emitting devices due to limitations. The inventors have found, after long-term research, that in order to solve the problem that the density of light-emitting devices cannot be further increased, isolation structures are provided in some display panels, and during the full-layer evaporation of light-emitting material layers and electrodes, the light-emitting material layers and the electrodes can be disconnected at the position of the isolation structures, and light-emitting devices of different colors can be formed in different isolation openings by means of multiple evaporation and multiple etching processes. The above process is also referred to as patterning of the light-emitting devices.

Relevant embodiments for isolation structures (or known as partition structures or isolation pillars) and encapsulation layers are described in Patent CN 118251982 A, patent 202410864269.8, patent PCT/CN 2024/098407, patent PCT/CN 2024/102783, patent PCT/CN 2024/098217, patent PCT/CN 2024/100935, patent PCT/CN 2024/102785, patent PCT/CN 2024/099419, patent PCT/CN 2024/099072 and patent CN 116685174 A, the contents of which are incorporated herein by reference for reference.

In the above-mentioned display panels, the display effect of the display panels may be affected directly by the lapping between the electrodes and the isolation structures. For example, the poor lapping between the electrodes and the isolation structures may lead to abnormal display of the light-emitting devices, thus affecting the display effect of the display panels.

In order to solve the above problem, the inventors have innovatively designed the following embodiments. The specific implementations of the present application will be described in detail below with reference to the accompanying drawings. It should be noted that the defects of the above solutions in the prior art are the results obtained by the inventors after practice and careful research. Therefore, the process of discovering the above problem and the solutions proposed in the following embodiments for the above problem should be regarded as the contributions made by the embodiments to the present application during invention and creation, and should not be construed as the content.

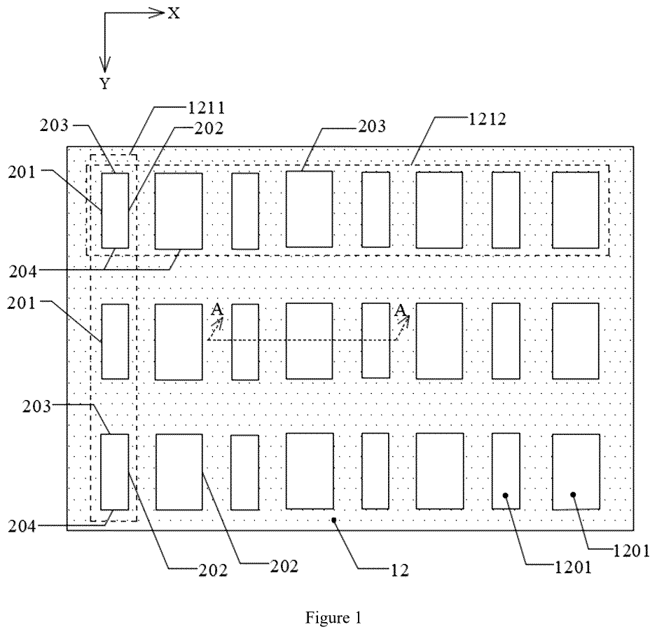

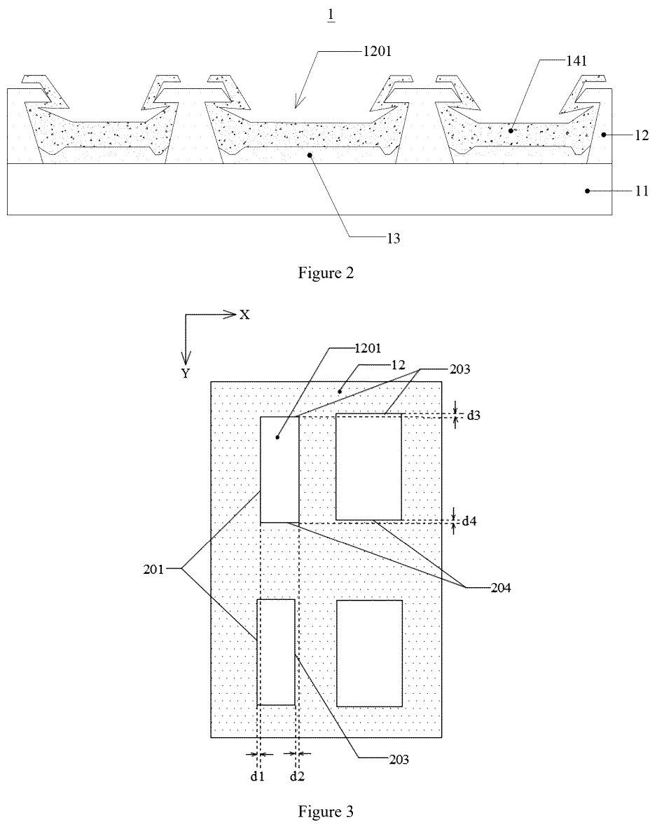

Referring to FIGS. 1 and 2, FIG. 1 illustrates a schematic diagram of a position relationship between an isolation structure and isolation openings in a display panel according to an embodiment, and FIG. 2 illustrates a schematic cross-sectional diagram of position AA in FIG. 1. In this embodiment, the display panel 1 includes a substrate 11 and an isolation structure 12. The isolation structure 12 is located on the substrate 11. The isolation structure 12 includes a plurality of isolation openings 1201. The plurality of isolation openings 1201 are arrayed in a plurality of columns 1211 of isolation openings arranged in a second direction (direction X in the figures), and each column 1211 of isolation openings extends in a first direction (direction Y in the figures), where the first direction intersects the second direction.

A contour line of an orthographic projection of each isolation opening 1201 on the substrate 11 includes a first contour line 201 extending in the first direction and located on a side of the isolation opening 1201 and a second contour line 202 located on a side opposite the side where the first contour line 201 is located and extending in the first direction. That is, both the first contour line 201 and the second contour line 202 extend in the first direction and are located on opposite sides of the isolation opening 1201.

In the same column 1211 of isolation openings, the first contour lines 201 of different isolation openings 1201 are flush, and the second contour lines 202 of different isolation openings 1201 are flush.

In this embodiment, the display panel 1 further includes light-emitting devices 13 and encapsulation units 141, where at least part of the light-emitting devices 13 are located in the isolation openings 1201, and the encapsulation units 141 are used for encapsulating the light-emitting devices 13 in the isolation openings 1201.

In the above structure, when the isolation structure 12 is laterally etched by an etching solution, the etching solution in one isolation opening 1201 may be transferred into an adjacent isolation opening 1201 when it overflows. In the column 1211 of isolation openings, as the first contour lines 201 of different isolation openings 1201 are flush and the second contour lines 202 of different isolation openings 1201 are flush, the overflowing etching solution can be transferred into the adjacent isolation openings 1201 in the first direction more easily, and a channel for fast flow of the etching solution can be formed in the first direction (direction Y in the figures), so as to avoid problems of gathering or accumulation of the etching solution at some positions, so that the amount of lateral etching of the isolation structure 12 at different positions is uniform, ensuring product quality and yield and improving display effect of the display panel 1.

Further, in this embodiment, referring again to FIG. 1, the plurality of isolation openings 1201 are also arrayed in a plurality of rows 1212 of isolation openings arranged in the first direction (direction Y in the figures), and each row 1212 of isolation openings extends in the second direction (direction X in the figures). As an example, the first direction may be perpendicular to the second direction. That is, the rows 1212 of isolation openings are perpendicular to the columns 1211 of isolation openings.

It should be noted that there is no difference between the columns 1211 of isolation openings and the rows 1212 of isolation openings, and the columns 1211 of isolation openings and the rows 1212 of isolation openings merely indicate arrangements of the isolation openings 1201 in different directions, i.e. for distinguishing the arrangements of the isolation openings 1201 in different directions. For example, in other embodiments, the isolation openings 1201 arranged in the first direction may also form the rows 1212 of isolation openings, and the isolation openings 1201 arranged in the second direction may also form the columns 1211 of isolation openings.

Referring again to FIG. 1, the contour line of the orthographic projection of the isolation opening 1201 on the substrate 11 includes a third contour line 203 extending in the second direction (direction X in the figures) and located on a side of the isolation opening 1201 and a fourth contour line 204 located on a side opposite the side where the third contour line 203 is located and extending in the second direction. That is, both the third contour line 203 and the fourth contour line 204 extend in the second direction and are located on opposite sides of the isolation opening 1201.

In the same row 1212 of isolation openings, the third contour lines 203 of at least part of the isolation openings 1201 are flush, and the fourth contour lines 204 of at least part of the isolation openings 1201 are flush. In one embodiment, in the same row 1212 of isolation openings, the third contour lines 203 of all the isolation openings 1201 are flush and the fourth contour lines 204 of all the isolation openings 1201 are flush.

When the isolation structure 12 is laterally etched by an etching solution, the etching solution in one isolation opening 1201 may be transferred into an adjacent isolation opening 1201 when it overflows. In the row 1212 of isolation openings, the third contour lines 203 of different isolation openings 1201 are flush and the fourth contour lines 204 of different isolation openings 1201 are flush, so that the overflowing etching solution can be transferred into the adjacent isolation openings 1201 in the second direction more easily, and a channel for fast flow of the etching solution can be formed in the second direction (direction X in the figures). That is, in this embodiment, the channel for fast flow of the etching solution may be formed in the first direction or the second direction, which can accelerate the flow rate of the etching solution and avoid gathering or accumulation of the etching solution at some positions, so that the isolation structure 12 at different positions is acted upon by the etching solution for the same time and the amount of lateral etching of the isolation structure 12 at the different positions is uniform, thus ensuring product quality and yield.

In this embodiment, different contour lines being flush means that an alignment error between different contour lines is within an allowable range of process precision.

That is, as long as the error between different contour lines is within the allowable range of process precision, it can be considered that the different contour lines are flush with each other.

Referring to FIGS. 1 and 3, in the same column 1211 of isolation openings, a distance d1 between a point on the first contour line 201 of the isolation opening 1201 and a point on the first contour line 201 of an adjacent isolation opening 1201 in the second direction (direction X in the figures) is less than or equal to 3 μm, which can be considered that the first contour lines 201 of different isolation openings 1201 in the same column 1211 of isolation openings are flush. As an example, the distance d1 includes 0 μm, 0.5 μm, 1 μm, 1.5 μm, 2.0 μm, 2.5 μm, or 3 μm, etc. A distance d2 between a point on the second contour line 202 of the isolation opening 1201 and a point on the second contour line 202 of an adjacent isolation opening 1201 in the second direction is less than or equal to 3 μm, which can be considered that the second contour lines 202 of different isolation openings 1201 in the same column 1211 of isolation openings are flush. As an example, the distance d2 includes 0 μm, 0.5 μm, 1 μm, 1.5 μm, 2.0 μm, 2.5 μm, or 3 μm, etc.

Referring again to FIGS. 1 and 3, in the same row 1212 of isolation openings, a distance d3 between a point on the third contour line 203 of the isolation opening 1201 and a point on the third contour line 203 of at least part of adjacent isolation openings 1201 in the first direction (direction Y in the figures) is less than or equal to 3 μm, which can be considered that the third contour lines 203 of at least part of the isolation openings 1201 in the same row 1212 of isolation openings are flush. As an example, the distance d3 includes 0 μm, 0.5 μm, 1 μm, 1.5 μm, 2.0 μm, 2.5 μm, or 3 μm, etc. A distance d4 between a point on the fourth contour line 204 of the isolation opening 1201 and a point on the fourth contour line 204 of at least part of adjacent isolation openings 1201 in the first direction is less than or equal to 3 μm, which can be considered that the fourth contour line 204 of at least part of the isolation openings 1201 in the same row 1212 of isolation openings are flush. As an example, the distance d4 includes 0 μm, 0.5 μm, 1 μm, 1.5 μm, 2.0 μm, 2.5 μm, or 3 μm, etc.

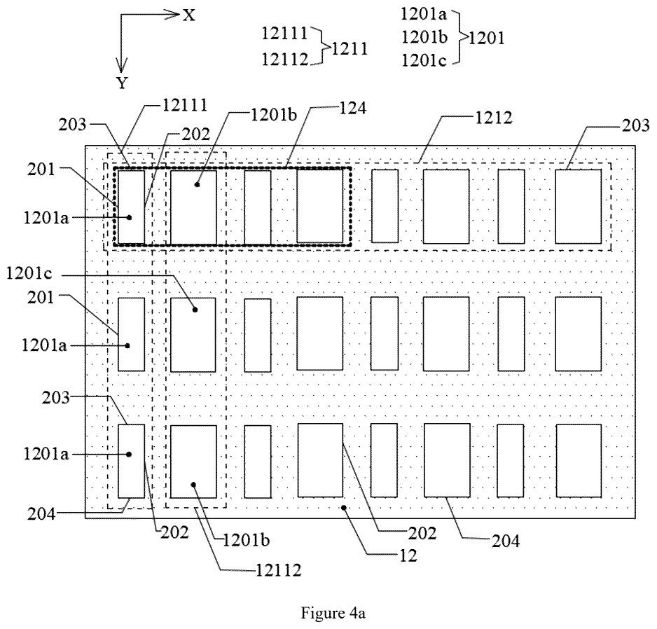

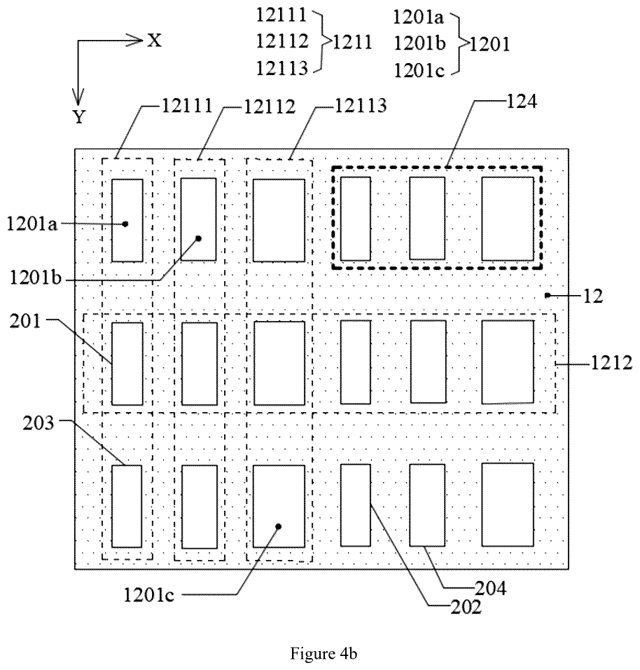

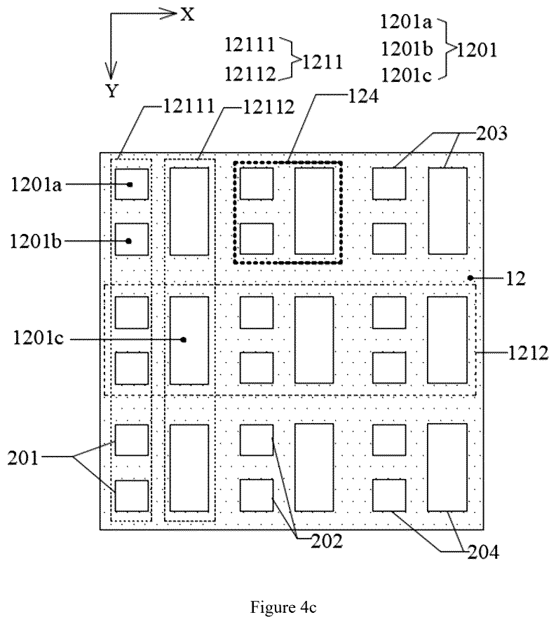

Referring to FIG. 4a, in a possible implementation of this embodiment, the columns 1211 of isolation openings include a first column 12111 of isolation openings and a second column 12112 of isolation openings that are adjacent to each other, and the isolation openings 1201 include first isolation openings 1201a, second isolation openings 1201b, and third isolation openings 1201c. A plurality of first isolation openings 1201a are distributed in the first direction (direction Y in the figures) to form the first column 12111 of isolation openings. The second isolation openings 1201b and the third isolation openings 1201c are arranged alternately in the first direction (direction Y in the figures) to form the second column 12112 of isolation openings. One first isolation opening 1201a, one second isolation opening 1201b, another first isolation opening 1201a and one third isolation opening 1201c form an isolation opening unit 124, and a plurality of isolation opening units 124 are arranged in the second direction (direction X in the figures) to form the row 1212 of isolation openings.

In the first column 12111 of isolation openings, the first contour lines 201 of different first isolation openings 1201a are flush and the second contour lines 202 of different first isolation openings 1201a are flush.

In the second column 12112 of isolation openings, the first contour lines 201 of the second isolation openings 1201b and the first contour lines 201 of the third isolation openings 1201c are flush, and the second contour lines 202 of the second isolation openings 1201b and the second contour lines 202 of the third isolation openings 1201c are flush.

In one embodiment, in the same row 1212 of isolation openings, the third contour lines 203 of the first isolation openings 1201a, the third contour lines 203 of the second isolation openings 1201b and the third contour lines 203 of the third isolation openings 1201c are flush, and the fourth contour lines 204 of the first isolation openings 1201a, the fourth contour lines 204 of the second isolation openings 1201b and the fourth contour lines 204 of the third isolation openings 1201c are flush.

Referring to FIG. 4b, in another possible implementation of this embodiment, the columns 1211 of isolation openings include a first column 12111 of isolation openings, a second column 12112 of isolation openings and a third column 12113 of isolation openings that are adjacent to each other, and the isolation openings 1201 include first isolation openings 1201a, second isolation openings 1201b and third isolation openings 1201c. A plurality of first isolation openings 1201a are distributed in the first direction (direction Y in the figures) to form the first column 12111 of isolation openings, a plurality of second isolation openings 1201b are distributed in the first direction to form the second column 12112 of isolation openings, and a plurality of third isolation openings 1201c are distributed in the first direction to form the third column 12113 of isolation openings.

In this embodiment, one first isolation opening 1201a, one second isolation opening 1201b and one third isolation opening 1201c form an isolation opening unit 124, and a plurality of isolation opening units 124 are arranged in the second direction (direction X in the figures) to form the row 1212 of isolation openings.

In the same first column 12111 of isolation openings, the first contour lines 201 of different first isolation openings 1201a are flush, and the second contour lines 202 of different first isolation openings 1201a are also flush.

In the same second column 12112 of isolation openings, the first contour lines 201 of different second isolation openings 1201b are flush, and the second contour lines 202 of different second isolation openings 1201b are also flush.

In the same third column 12113 of isolation openings, the first contour lines 201 of different third isolation openings 1201c are flush, and the second contour lines 202 of different third isolation openings 1201c are also flush.

In the same row 1212 of isolation openings, the third contour lines 203 of the first isolation openings 1201a, the third contour lines 203 of the second isolation openings 1201b and the third contour lines 203 of the third isolation openings 1201c are flush, and the fourth contour lines 204 of the first isolation openings 1201a, the fourth contour lines 204 of the second isolation openings 1201b and the fourth contour lines 204 of the third isolation openings 1201c are flush.

Referring to FIG. 4c, in yet another possible implementation of this embodiment, the columns 1211 of isolation openings include a first column 12111 of isolation openings and a second column 12112 of isolation openings that are adjacent to each other, and the isolation openings 1201 include first isolation openings 1201a, second isolation openings 1201b, and third isolation openings 1201c. The first isolation openings 1201a and the second isolation openings 1201b are arranged alternately in the first direction (direction Y in the figures) to form the first column 12111 of isolation openings. A plurality of third isolation openings 1201c are arranged in the first direction (direction Y in the figures) to form the second column 12112 of isolation openings.

In this embodiment, one first isolation opening 1201a, one second isolation opening 1201b and one third isolation opening 1201c form an isolation opening unit 124, and a plurality of isolation opening units 124 are arranged in the second direction to form the row 1212 of isolation openings.

In the first column 12111 of isolation openings, the first contour lines 201 of the first isolation openings 1201a and the first contour lines 201 of the second isolation openings 1201b are flush, and the second contour lines 202 of the first isolation openings 1201a and the second contour lines 202 of the second isolation openings 1201b are flush.

In the second column 12112 of isolation openings, the first contour lines 201 of different third isolation openings 1201c are flush, and the second contour lines 202 of different third isolation openings 1201c are flush.

In this implementation, in the same row 1212 of isolation openings, the third contour lines 203 of the first isolation openings 1201a and the third contour lines 203 of the third isolation openings 1201c are flush, and the fourth contour lines 204 of the second isolation openings 1201b and the fourth contour lines 204 of the third isolation openings 1201c are flush. That is, in the arrangement shown in FIG. 4c, the first isolation opening 1201a has a third contour line 203 flush with the third contour line 203 of the adjacent third isolation opening 1201c, and the second isolation opening 1201b has a fourth contour line 204 flush with the fourth contour line 204 of the adjacent third isolation opening 1201c.

In this embodiment, in the same column 1211 of isolation openings, the orthographic projections of different isolation openings 1201 on the substrate 11 have the same shape and area size. As an example, in the same column 1211 of isolation openings, the orthographic projections of different isolation openings 1201 on the substrate 11 may be rectangles having the same area.

The orthographic projections of the isolation openings 1201 in different columns 1211 of isolation openings on the substrate 11 have the same or similar shape, and the orthographic projections of the isolation openings 1201 in different columns 1211 of isolation openings on the substrate 11 have the same or different area size. As an example, in some implementations, the orthographic projections of the isolation openings 1201 in different columns 1211 of isolation openings on the substrate 11 may have the same shape or area size. In some other implementations, the orthographic projections of the isolation openings 1201 in different columns 1211 of isolation openings on the substrate 11 may have similar shape and different area size.

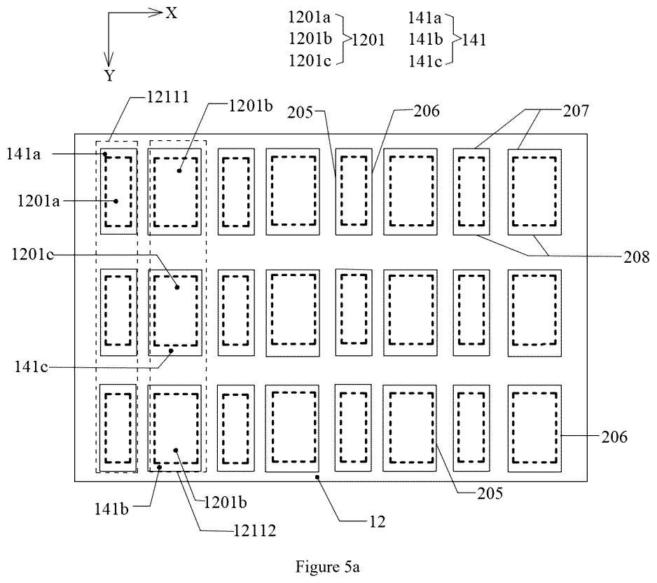

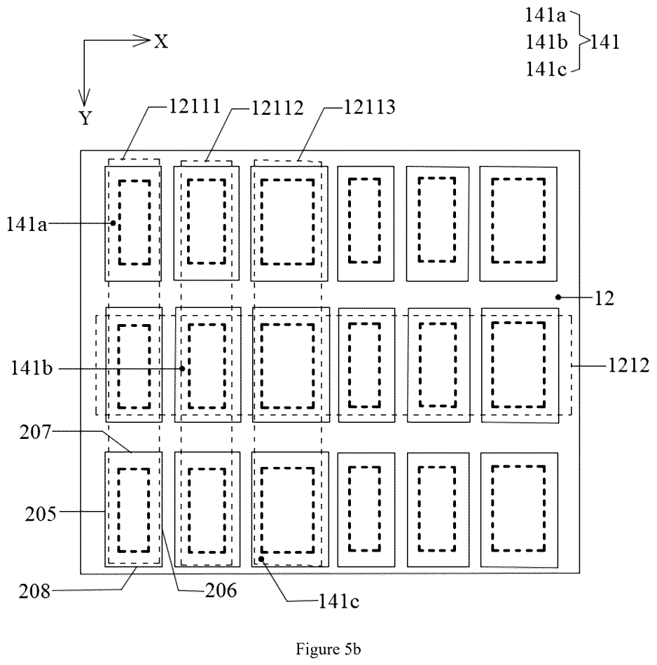

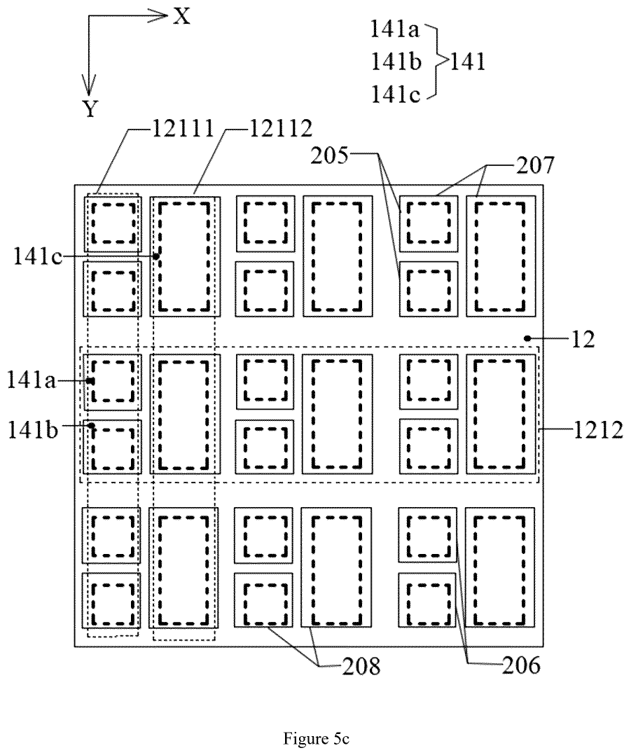

Referring to FIG. 5a, a contour line of an orthographic projection of each encapsulation unit 141 on the substrate 11 includes a fifth contour line 205 extending in the first direction (direction Y in the figures) and located on a side of the encapsulation unit 141 and a sixth contour line 206 located a side opposite the side where the fifth contour line 205 is located and extending in the first direction. That is, both the fifth contour line 205 and the sixth contour line 206 extend in the first direction and are located on opposite sides of the encapsulation unit 141.

The fifth contour lines 205 of different encapsulation units 141 for encapsulating the light-emitting devices 13 in different isolation openings 1201 in the same column 1211 of isolation openings are flush, and the sixth contour lines 206 of different encapsulation unit 141 for encapsulating the light-emitting devices 13 in different isolation openings 1201 in the same column 1211 of isolation openings are flush.

The above structure enables the different encapsulation units 141 to have aligned edges in the first direction and thus the different encapsulation units 141 to have more balanced structures in the first direction, so that the different encapsulation units 141 can evenly share an external force applied thereon, thus avoiding damage to the encapsulation units 141, facilitating the improvement of the overall structural stability of the encapsulation units 141 and ensuring the encapsulation effectiveness of the encapsulation units.

Further, referring to FIGS. 5a, 5b and 5c, the contour line of the orthographic projection of the encapsulation unit 141 on the substrate 11 includes a seventh contour line 207 extending in the second direction (direction X in the figures) and located on a side of the encapsulation unit and an eighth contour line 208 located on a side opposite the side where the seventh contour line 207 is located and extending in the second direction. That is, both the seventh contour line 207 and the eighth contour line 208 extend in the second direction and are located on opposite sides of the encapsulation unit 141.

The encapsulation units 141 include first encapsulation units 141a, second encapsulation units 141b and third encapsulation units 141c. The first encapsulation units 141a are used for encapsulating the light-emitting devices 13 in the first isolation openings 1201a, the second encapsulation units 141b are used for encapsulating the light-emitting devices 13 in the second isolation openings 1201b, and the third encapsulation units 141c are used for encapsulating the light-emitting devices 13 in the third isolation openings 1201c.

In this embodiment, two adjacent encapsulation units 141 for encapsulating the light-emitting devices 13 are disconnected on a side of the isolation structure 12 away from the substrate 11, that is, two adjacent encapsulation units 141 for encapsulating the light-emitting devices 13 of different luminous colors or the same luminous color are disconnected on the side of the isolation structure 12 away from the substrate 11, which can be ensured that no light-emitting material layer remains on the isolation structure 12 between the adjacent isolation openings 1201, avoiding the problem of abnormal color appearance of the display panel.

In a possible implementation, as shown in FIGS. 5a and 5b, the seventh contour lines 207 of the encapsulation units 141 for encapsulating the light-emitting devices 13 in different isolation openings 1201 in the same row 1212 of isolation openings are flush, and the eighth contour lines 208 of the encapsulation units 141 for encapsulating the light-emitting devices 13 in different isolation openings 1201 in the same row 1212 of isolation openings are flush.

In another possible implementation, as shown in FIG. 5c, the seventh contour lines 207 of the first encapsulation units 141a and the third encapsulation units 141c for encapsulating the light-emitting devices 13 in different isolation openings 1201 in the same row 1212 of isolation openings are flush, and the eighth contour lines 208 of the second encapsulation units 141b and the third encapsulation units 141c for encapsulating the light-emitting devices 13 in different isolation openings 1201 in the same row 1212 of isolation openings are flush. That is, in the arrangement shown in FIG. 5c, the first encapsulation unit 141a has a seventh contour line 207 flush with the seventh contour line 207 of the adjacent third encapsulation unit 141c, and the second encapsulation unit 141b has an eighth contour line 208 flush with the eighth contour line 208 of the adjacent third encapsulation unit 141c.

The above structure also enables the different encapsulation units 141 to have aligned edges in the second direction are aligned and thus the different encapsulation units 141 to have more balanced structures in the second direction, so that the different encapsulation units 141 can evenly share an external force applied thereon, thus avoiding damage to the encapsulation units 141, facilitating the improvement of the overall structural stability of the encapsulation units 141 and ensuring the encapsulation effectiveness of the encapsulation units.

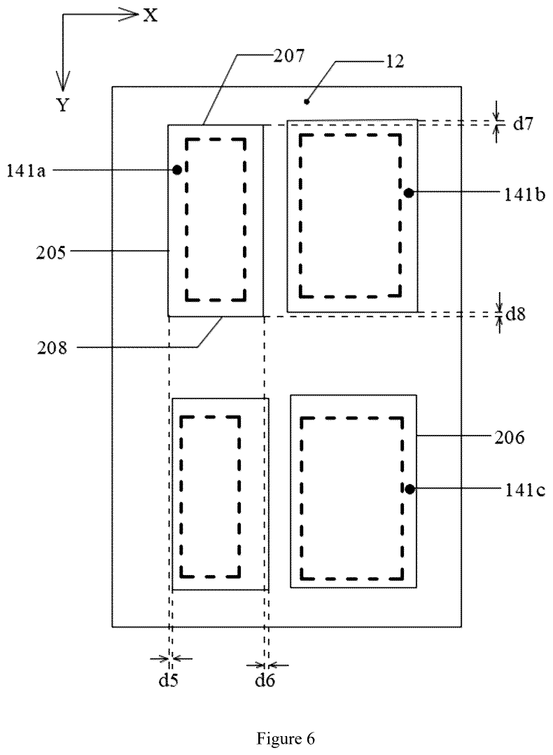

In this embodiment, referring to FIGS. 5a and 6, a distance d5 between the fifth contour lines 205 of adjacent encapsulation units 141 for encapsulating the light-emitting devices 13 in different isolation openings 1201 in the same column 1211 of isolation openings in the second direction (direction X in the figures) is less than or equal to 3 μm, which can be considered that the fifth contour lines 205 of different encapsulation units 141 for encapsulating the light-emitting devices 13 in different isolation openings 1201 in the same column 1211 of isolation openings are aligned. As an example, the distance d5 includes 0 μm, 0.5 μm, 1 μm, 1.5 μm, 2.0 μm, 2.5 μm, or 3 μm, etc. A distance d6 between the sixth contour lines 206 of adjacent encapsulation units 141 for encapsulating the light-emitting devices 13 in different isolation openings 1201 in the same column 1211 of isolation openings in the second direction is less than or equal to 3 μm, which can be considered that the sixth contour lines 206 of different encapsulation units 141 for encapsulating the light-emitting devices 13 in different isolation openings 1201 in the same column 1211 of isolation openings are aligned. As an example, the distance d6 includes 0 μm, 0.5 μm, 1 μm, 1.5 μm, 2.0 μm, 2.5 μm, or 3 μm, etc.

In an implementation, referring to FIGS. 5a, 5b and 6, a distance d7 between the seventh contour lines 207 of adjacent encapsulation units 141 for encapsulating the light-emitting devices 13 in different isolation openings 1201 in the same row 1212 of isolation openings in the first direction (direction Y in the figures) is less than or equal to 3 μm, which can be considered that the seventh contour lines 207 of the encapsulation units 141 for encapsulating the light-emitting devices 13 in different isolation openings 1201 in the same row 1212 of isolation openings are aligned. As an example, the distance d7 includes 0 μm, 0.5 μm, 1 μm, 1.5 μm, 2.0 μm, 2.5 μm, or 3 μm, etc. A distance d8 between the eighth contour lines 208 of adjacent encapsulation units 141 for encapsulating the light-emitting devices 13 in different isolation openings 1201 in the same row 1212 of isolation openings in the first direction is less than or equal to 3 μm, which can be considered that the eighth contour lines 208 of the encapsulation units 141 for encapsulating the light-emitting devices 13 in different isolation openings 1201 in the same row 1212 of isolation openings are aligned. As an example, the distance d8 includes 0 μm, 0.5 μm, 1 μm, 1.5 μm, 2.0 μm, 2.5 μm, or 3 μm, etc.

In another implementation, referring to FIGS. 5c and 6, the contour lines of part of the encapsulation units 141 for encapsulating the light-emitting devices 13 in different isolation openings 1201 in the same row 1212 of isolation openings are aligned. A distance d7 between the seventh contour lines 207 of the first encapsulation units 141a and the third encapsulation units 141c for encapsulating the light-emitting devices 13 in different isolation openings 1201 in the same row 1212 of isolation openings in the first direction is less than or equal to 3 μm, which can be considered that the seventh contour lines 207 of the first encapsulation units 141a and the third encapsulation units 141c for encapsulating the light-emitting devices 13 in different isolation openings 1201 in the same row 1212 of isolation openings are aligned. As an example, the distance d7 includes 0 μm, 0.5 μm, 1 μm, 1.5 μm, 2.0 μm, 2.5 μm or 3 μm, etc. A distance d8 between the eighth contour lines 208 of the second encapsulation units 141b and the third encapsulation units 141c for encapsulating the light-emitting devices 13 in different isolation openings 1201 in the same row 1212 of isolation openings in the first direction is less than or equal to 3 μm, which can be considered that the eighth contour lines 208 of the second encapsulation units 141b and the third encapsulation units 141c for encapsulating the light-emitting devices 13 in different isolation openings 1201 in the same row 1212 of isolation openings are aligned. As an example, the distance d8 includes 0 μm, 0.5 μm, 1 μm, 1.5 μm, 2.0 μm, 2.5 μm or 3 μm, etc.

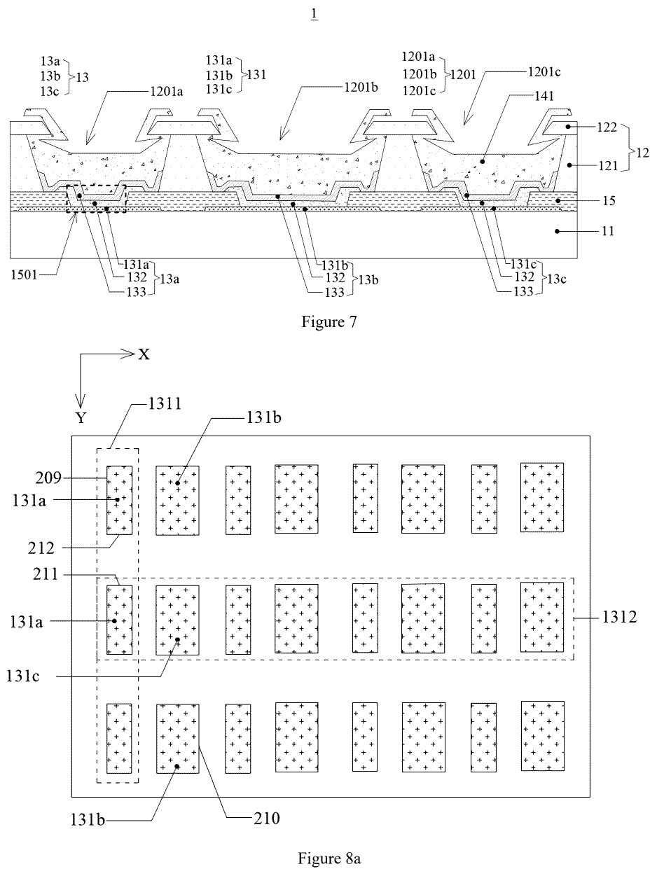

Further, referring to FIG. 7, in a direction away from the substrate 11, each light-emitting device 13 includes a first electrode 131, a light-emitting material layer 132 and a second electrode 133 that are stacked. The first electrode 131 is located on a side of the isolation structure 12 facing the substrate 11, and the second electrode 133 laps with the isolation structure 12.

In one embodiment, the light-emitting devices 13 include first light-emitting devices 13a, second light-emitting devices 13b and third light-emitting devices 13c of different luminous colors, where at least part of the first light-emitting devices 13a are located in the first isolation openings 1201a, at least part of the second light-emitting devices 13b are located in the second isolation openings 1201b and at least part of the third light-emitting devices 13c are located in the third isolation openings 1201c.

Referring again to FIG. 7, in the direction away from the substrate 11, the isolation structure 12 includes a first isolation part 121 and a second isolation part 122 that are stacked, the second electrode 133 lapping with the second isolation part 122. An orthographic projection of the first isolation part 121 on the substrate 11 is located within an orthographic projection of the second isolation part 122 on the substrate 11. That is, the second isolation part 122 protrudes relative to the first isolation part 121. The contour line of the orthographic projection of the isolation opening 1201 on the substrate 11 is formed of an orthographic projection, on the substrate 11, of an edge of a side of the second isolation part 122 facing the isolation opening 1201.

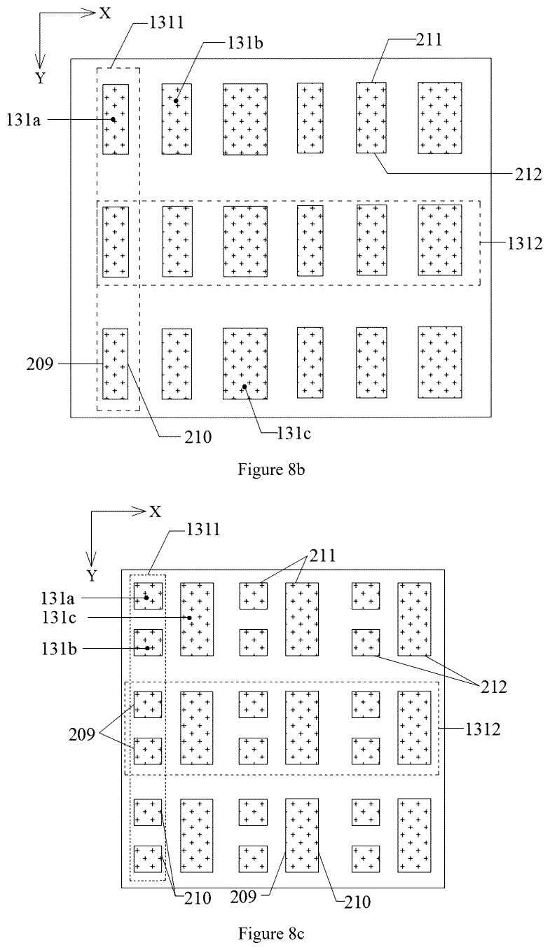

In this embodiment, referring to FIG. 8a, an orthographic projection of the first electrode 131 on the substrate 11 at least partially overlaps the orthographic projection of the isolation opening 1201 on the substrate 11. A plurality of first electrodes 131 are arrayed in a plurality of columns 1311 of first electrodes arranged in the second direction (direction X in the figures). A contour line of the orthographic projection of the first electrode 131 on the substrate 11 includes a ninth contour line 209 extending in the first direction and located on a side of the first electrode 131 and a tenth contour line 210 located on a side opposite the side where the ninth contour line 209 is located and extending in the first direction.

In the same column 1311 of first electrodes, the ninth contour lines 209 of different first electrodes 131 are flush, and the tenth contour lines 210 of different first electrodes 131 are flush.

In this embodiment, the first electrode 131 is generally formed by using an ITO/Ag/ITO three-layer conductive structure by means of wet-etching patterning. In the same column 1311 of first electrodes, the ninth contour lines 209 of different first electrodes 131 are flush and the tenth contour lines 210 of different first electrodes 131 are flush, and a channel for fast flow of the etching solution can be formed in the first direction (direction Y in the figures), which can ensure that Ag in the middle is not over-etched, thus avoiding the impact on the conductive effect of the first electrode 131 and ensuring a good conductive effect of the first electrode 131.

Further, the plurality of first electrodes 131 are also arrayed in a plurality rows 1312 of first electrodes arranged in the first direction (direction Y in the figures), where the first direction and the second direction intersect. As an example, the first direction may be perpendicular to the second direction.

It should be noted that there is no difference between the columns 1311 of first electrodes and the rows 1312 of first electrodes, and the columns 1311 of first electrodes and the rows 1312 of first electrodes merely indicate arrangements of the first electrodes in different directions, i.e. for distinguishing the arrangements of the first electrodes in different directions. For example, in other embodiments, the first electrodes 131 arranged in the first direction may also form the rows 1312 of first electrodes, and the first electrodes 131 arranged in the second direction may also form the columns 1311 of first electrodes.

Referring to FIGS. 8a, 8b and 8c, the contour line of the orthographic projection of the first electrode 131 on the substrate 11 includes an eleventh contour line 211 extending in the second direction (direction X in the figures) and located on a side of the first electrode 131 and a twelfth contour line 212 located on a side opposite the side where the eleventh contour line 211 is located and extending in the second direction. That is, both the eleventh contour line 211 and the twelfth contour line 212 extend in the second direction and are located on opposite sides of the first electrode 131. In this embodiment, the first electrodes 131 include first sub-electrodes 131a, second sub-electrodes 131b and third sub-electrodes 131c. An orthographic projection of each first sub-electrode 131a on the substrate 11 at least partially overlaps an orthographic projection of each first isolation opening 1201a on the substrate 11, an orthographic projection of each second sub-electrode 131b on the substrate 11 at least partially overlaps an orthographic projection of each second isolation opening 1201b on the substrate 11, and an orthographic projection of each third sub-electrode 131c on the substrate 11 at least partially overlaps an orthographic projection of each third isolation opening 1201c on the substrate 11.

In an implementation of this embodiment, referring to FIGS. 8a and 8b, in the same row 1312 of first electrodes, the eleventh contour lines 211 of different first electrodes 131 are flush, and the twelfth contour lines 212 of different first electrodes 131 are flush. That is, in the same row 1312 of first electrodes, the eleventh contour lines 211 of the first sub-electrodes 131a, the eleventh contour lines 211 of the second sub-electrodes 131b and the eleventh contour lines 211 of the third sub-electrodes 131c are aligned, and the twelfth contour lines 212 of the first sub-electrodes 131a, the twelfth contour lines 212 of the second sub-electrodes 131b and the twelfth contour lines 212 of the third sub-electrodes 131c are also aligned.

In another implementation of this embodiment, referring to FIG. 8c, in the same row 1312 of first electrodes, the eleventh contour lines 211 of the first sub-electrodes 131a and the eleventh contour lines 211 of the third sub-electrodes 131c are flush, and the twelfth contour lines 212 of the second sub-electrodes 131b and the twelfth contour lines 212 of the third sub-electrodes 131c are flush. That is, in the arrangement shown in FIG. 8c, the first sub-electrode 131a has an eleventh contour line 211 flush with the eleventh contour line 211 of the adjacent third sub-electrode 131c, and the second sub-electrode 131b has a twelfth contour line 212 flush with the twelfth contour line 212 of the adjacent third sub-electrode 131c.

With the above design, the channels for fast flow of the etching solution may be formed in both the first direction (direction Y in the figures) and the second direction (direction X in the figures) during forming of the first electrode 131 by wet-etching patterning, which can ensure that the etching time of the etching solution at different positions is substantially the same, ensuring that all sides of the first electrode can be uniformly laterally etched, avoiding over-etching of the Ag layer in the middle, and ensuring a good conductive effect of the first electrode 131.

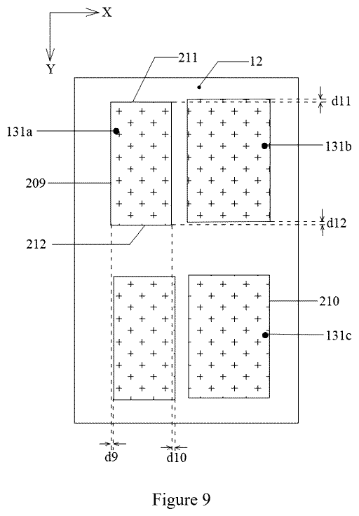

In this embodiment, referring to FIGS. 8a and 9, in the same column 1311 of first electrodes, a distance d9 between a point on the ninth contour line 209 of the first electrode 131 and a point on the ninth contour line 209 of an adjacent first electrode 131 in the second direction (direction X in the figures) is less than or equal to 3 μm, which can be considered that the ninth contour lines 209 of different first electrodes 131 are aligned. As an example, the distance d9 includes 0 μm, 0.5 μm, 1 μm, 1.5 μm, 2.0 μm, 2.5 μm or 3 μm, etc. In the same column 1311 of first electrodes, a distance d10 between a point on the tenth contour line 210 of the first electrode 131 and a point on the tenth contour line 210 of an adjacent first electrode 131 in the second direction is less than or equal to 3 μm, which can be considered that the tenth contour lines 210 of different first electrodes 131 are aligned. As an example, the distance d10 includes 0 μm, 0.5 μm, 1 μm, 1.5 μm, 2.0 μm, 2.5 μm, or 3 μm, etc.

In a possible implementation of this embodiment, referring to FIGS. 8a, 8b and 9, in the same row 1312 of first electrodes, a distance d11 between a point on the eleventh contour line 211 of the first electrode 131 and a point on the eleventh contour line 211 of an adjacent first electrode 131 in the first direction (direction Y in the figures) is less than or equal to 3 μm, which can be considered that the eleventh contour lines 211 of different first electrodes 131 in the same row 1312 of first electrodes are flush. As an example, the distance d11 includes 0 μm, 0.5 μm, 1 μm, 1.5 μm, 2.0 μm, 2.5 μm, or 3 μm, etc. In the same row 1312 of first electrodes, a distance d12 of a point on the twelfth contour line 212 of the first electrode 131 and a point on the twelfth contour line 212 of an adjacent first electrodes 131 in the first direction is less than or equal to 3 μm, which can be considered that the twelfth contour lines 212 of different first electrodes 131 in the same row 1312 of first electrodes are flush. As an example, the distance d12 includes 0 μm, 0.5 μm, 1 μm, 1.5 μm, 2.0 μm, 2.5 μm, or 3 μm, etc.

In another possible implementation of this embodiment, referring to FIGS. 8c and 9, in the same row 1312 of first electrodes, a distance d11 between a point on the eleventh contour line 211 of the first sub-electrode 131a and a point on the eleventh contour line 211 of an adjacent third sub-electrode 131c in the first direction is less than or equal to 3 μm, which can be considered that in the same row 1312 of first electrodes, the eleventh contour lines 211 of part of the first electrodes 131 are flush. As an example, the distance d11 includes 0 μm, 0.5 μm, 1 μm, 1.5 μm, 2.0 μm, 2.5 μm, or 3 μm, etc. In the same row 1312 of first electrodes, a distance d12 between a point on the twelfth contour line 212 of the second sub-electrode 131b and a point on the twelfth contour line 212 of an adjacent third sub-electrode 131c in the first direction is less than or equal to 3 μm, which can be considered that in the same row 1312 of first electrodes, the twelfth contour lines 212 of part of the first electrodes 131 are flush. As an example, the distance d12 includes 0 μm, 0.5 μm, 1 μm, 1.5 μm, 2.0 μm, 2.5 μm, or 3 μm, etc.

Referring again to FIG. 7, in this embodiment, the display panel 1 further includes a pixel defining layer 15 on a side of the substrate 11, where the isolation structure 12 is located on a side of the pixel defining layer 15 away from the substrate 11. The first electrodes 131 are located on a side of the pixel defining layer 15 facing the substrate 11, the pixel defining layer 15 is provided with a plurality of pixel openings 1501, the pixel openings 1501 are in communication with the isolation openings 1201, and the first electrodes 131 are at least partially exposed from the pixel openings 1501. An orthographic projection of each pixel opening 1501 on the substrate 11 is located within the orthographic projection of the isolation opening 1201 on the substrate 11.

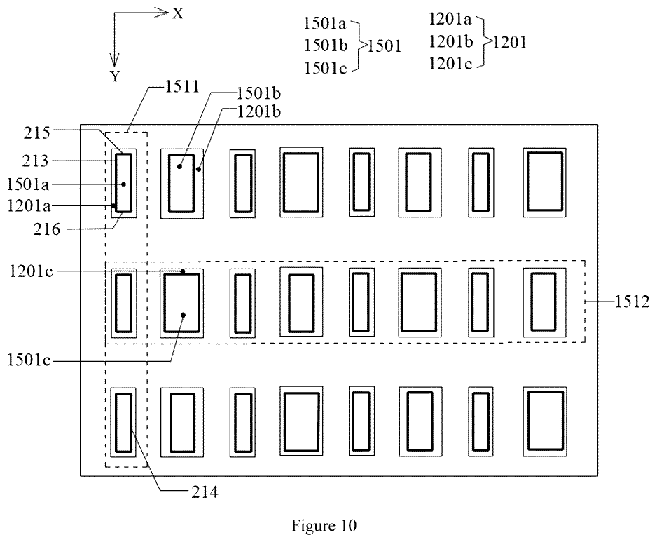

In this embodiment, referring to FIG. 10, the plurality of pixel openings 1501 are arrayed in a plurality of rows 1512 of pixel openings arranged in the first direction (direction Y in the figures). A contour line of the orthographic projection of the pixel opening 1501 on the substrate 11 includes a fifteenth contour line 215 extending in the second direction and located on a side of the pixel opening 1501 and a sixteenth contour line 216 located on a side opposite the side where the fifteenth contour line 215 is located and extending in the second direction. That is, both the fifteenth contour line 215 and the sixteenth contour line 216 extend in the second direction and are located on opposite sides of the pixel opening 1501.

In the same row 1512 of pixel openings, the fifteenth contour lines 215 of at least part of the pixel openings 1501 are flush and the sixteenth contour lines 216 of at least part of the pixel openings 1501 are flush.

Further, the plurality of pixel openings 1501 are also arrayed in a plurality of columns 1511 of pixel openings arranged in the second direction (direction X in the figures), where the first direction intersects the second direction. As an example, the first direction may be perpendicular to the second direction.

It should be noted that there is no difference between the columns 1511 of pixel openings and the rows 1512 of pixel openings, and the columns 1511 of pixel openings and the rows 1512 of pixel openings merely indicate arrangements of the pixel openings in different directions, i.e. for distinguishing the arrangements of the pixel openings in different directions For example, in other embodiments, the pixel openings 1501 arranged in the first direction may also form the rows 1512 of pixel openings, and the pixel openings 1501 arranged in the second direction may also form the columns 1511 of pixel openings.

The contour line of the orthographic projection of the pixel opening 1501 on the substrate 11 includes a thirteenth contour line 213 extending in the first direction and located on a side of the pixel opening 1501 and a fourteenth contour line 214 located on a side opposite the side where the thirteenth contour line 213 is located. That is, both the thirteenth contour line 213 and the fourteenth contour line 214 extend in the first direction and are located on opposite sides of the pixel opening 1501.

The pixel openings 1501 include first pixel openings 1501a, second pixel openings 1501b and third pixel openings 1501c. The first pixel openings 1501a are in communication with the first isolation openings 1201a, the second pixel openings 1501b are in communication with the second isolation openings 1201b, and the third pixel openings 1501c are in communication with the third isolation openings 1201c.

Referring to FIG. 10, in the same column 1511 of pixel openings, the thirteenth contour lines 213 of the same pixel openings 1501 are flush, and the fourteenth contour lines 214 of the same pixel openings 1501 are flush.

In this embodiment, orthographic projections of the first isolation openings 1201a, the second isolation openings 1201b and the third isolation openings 1201c on the substrate 11 have different area size, and accordingly, orthographic projections of the first pixel openings 1501a, the second pixel openings 1501b and the third pixel openings 1501c on the substrate 11 have different area size. As an example, the area of the orthographic projection of the pixel opening 1501 on the substrate 11 is positively correlated with the area of the orthographic projection of the corresponding isolation opening 1201 on the substrate 11, i.e., the larger the area of the orthographic projection of the pixel opening 1501 on the substrate 11, the larger the area of the orthographic projection of the isolation opening 1201 on the substrate 11.

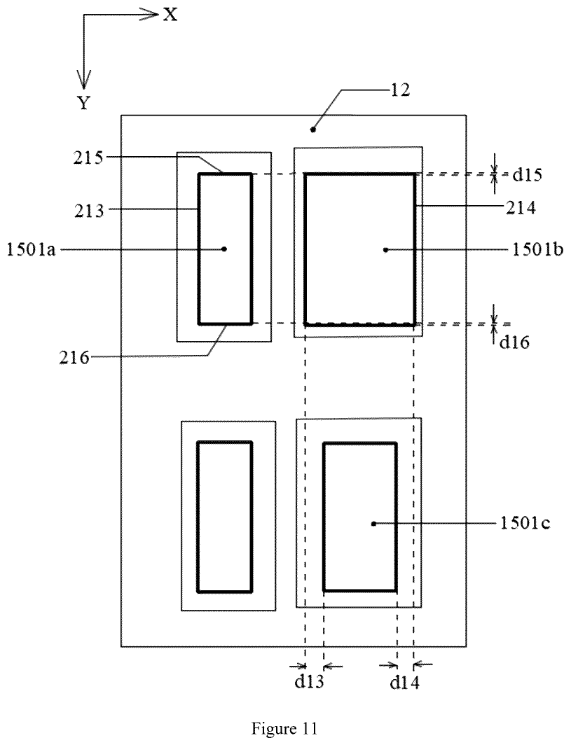

In this embodiment, referring to FIGS. 10 and 11, in the same column 1511 of pixel openings, a distance d13 between the thirteenth contour lines 213 of at least part of adjacent pixel openings 1501 in the second direction (direction X in the figures) is less than or equal to 3 μm, which can be considered that in the same column 1511 of pixel openings, the thirteenth contour lines 213 of at least part of the pixel openings 1501 are aligned. As an example, the distance d13 includes 0 μm, 0.5 μm, 1 μm, 1.5 μm, 2.0 μm, 2.5 μm, or 3 μm, etc. In the same column 1511 of pixel openings, a distance d14 between the fourteenth contour lines 214 of at least part of adjacent pixel openings 1501 in the second direction is less than or equal to 3 μm, which can be considered that in the same column 1511 of pixel openings, the fourteenth contour lines 214 of at least part of pixel openings 1501 are aligned. As an example, the distance d14 includes 0 μm, 0.5 μm, 1 μm, 1.5 μm, 2.0 μm, 2.5 μm, or 3 μm, etc.

In the same row 1512 of pixel openings, a distance d15 between the fifteenth contour lines 215 of the same pixel openings 1501 in the first direction is less than or equal to 3 μm, and a distance d16 between the sixteenth contour lines 216 of the same pixel openings 1501 in the first direction is less than or equal to 3 μm.

In the same row 1512 of pixel openings, a distance between the fifteenth contour lines 215 of different pixel openings 1501 in the first direction is greater than 3 μm, or a distance between the sixteenth contour lines 216 of different pixel openings 1501 in the first direction is greater than 3 μm.

With such a design, the area of each pixel opening can be controlled flexibly based on luminous efficiency of each light-emitting device so as to meet the display effect of the display panel.

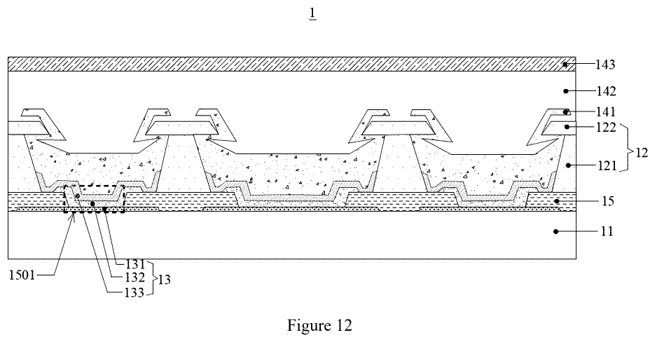

Further, in this embodiment, referring to FIG. 12, the display panel 1 further includes a first encapsulation layer 142. The first encapsulation layer 142 is located on a side of the encapsulation unit 141 away from the substrate 11, and the first encapsulation layer 142 covers at least the encapsulation units 141. The first encapsulation layer 142 includes a flat surface on a side away from the substrate 11.

Further, referring again to FIG. 12, the display panel 1 further includes a second encapsulation layer 143, the second encapsulation layer 143 being located on a side of the first encapsulation layer 142 away from the substrate 11.

In one embodiment, the encapsulation unit 141 and the second encapsulation layer 143 are inorganic encapsulation layers, and the first encapsulation layer 142 is an organic encapsulation layer. For example, the encapsulation unit 141 and the second encapsulation layer 143 may be formed by means of chemical vapor deposition (CVD), and the first encapsulation layer 142 may be formed by means of ink-jet printing (IJP).

It should be understood that the display panel 1 may further include film layers such as a touch-control function layer, an optical adhesive layer, a polarizer and a cover plate stacked sequentially on a side of the second encapsulation layer 143 away from the substrate 11. The above film layers are conventional film layers of the display panel and will not be repeated here.

An embodiment of the present application further provides an electronic device. The electronic device includes a display panel according to the present application, or includes a display panel prepared by a method for preparing a display panel according to this embodiment. The electronic device may include devices with a display function such as a smart phone, a tablet computer, a vehicle-mounted display device, a smart wearable device, a television, and a laptop computer.

Embodiments of the present application provide a display panel and an electronic device. In the display panel, an isolation structure is located on a substrate and includes a plurality of isolation openings, and the plurality of isolation openings are arrayed in a plurality of columns of isolation openings arranged in a second direction, where a contour line of an orthographic projection of each isolation opening on the substrate includes a first contour line and a second contour line that extend in a first direction and are located on opposite sides of the isolation opening, and in the same column of isolation openings, the first contour lines of different isolation openings are flush and the second contour lines of different isolation openings are flush. With such a design, when the isolation structure is laterally etched by an etching solution, a channel for fast flow of the etching solution is formed in the first direction, so as to avoid gathering or accumulation of the etching solution at some positions, so that the amount of lateral etching of the isolation structure at different positions is uniform, ensuring product quality and yield and improving display effect of the display panel.

The foregoing descriptions are merely exemplary embodiments of the present application, but are not intended to limit the present application. The present application may have various modifications and variations. Any modifications, equivalent substitutions, improvements, etc. made within the spirit and principle of the present application should fall within the scope of protection of the present application.

1. A display panel, comprising:
a substrate;
an isolation structure located on the substrate and comprising a plurality of isolation openings, the plurality of isolation openings being arrayed in a plurality of columns of isolation openings arranged in a second direction, wherein
a contour line of an orthographic projection of each isolation opening on the substrate comprises a first contour line extending in a first direction and located on a side of the isolation opening and a second contour line located on a side opposite the side where the first contour line is located and extending in the first direction; and in the same column of isolation openings, the first contour lines of different isolation openings are flush, and the second contour lines of different isolation openings are flush, the first direction intersecting the second direction;
light-emitting devices, at least part of the light-emitting devices being located in the isolation openings; and
encapsulation units for encapsulating the light-emitting devices in the isolation openings.

2. The display panel according to claim 1, wherein the plurality of isolation openings are also arrayed in a plurality of rows of isolation openings arranged in the first direction;
the contour line of the orthographic projection of the isolation opening on the substrate comprises a third contour line extending in the second direction and located on a side of the isolation opening and a fourth contour line located on a side opposite the side where the third contour line is located and extending in the second direction; and
in the same row of isolation openings, the third contour lines of at least part of the isolation openings are flush, and the fourth contour lines of at least part of the isolation openings are flush.

3. The display panel according to claim 2, wherein in the same column of isolation openings, a distance between a point on the first contour line of the isolation opening and a point on the first contour line of an adjacent isolation opening in the second direction is less than or equal to 3 μm, and a distance between a point on the second contour line of the isolation opening and a point on the second contour line of an adjacent isolation opening in the second direction is less than or equal to 3 μm; and
in the same row of isolation openings, a distance between a point on the third contour line of the isolation opening and a point on the third contour line of at least part of adjacent isolation openings in the first direction is less than or equal to 3 μm, and a distance between a point on the fourth contour line of the isolation opening and a point on the fourth contour line of at least part of adjacent isolation openings in the first direction is less than or equal to 3 μm.

4. The display panel according to claim 2, wherein the columns of isolation openings comprise a first column of isolation openings and a second column of isolation openings that are adjacent to each other, and the isolation openings comprise first isolation openings, second isolation openings, and third isolation openings;
a plurality of first isolation openings are distributed in the first direction to form the first column of isolation openings;
the second isolation openings and the third isolation openings are arranged alternately in the first direction to form the second column of isolation openings;
one second isolation opening, one first isolation opening, one third isolation opening, and another first isolation opening form an isolation opening unit, and a plurality of isolation opening units are arranged in the second direction to form the row of isolation openings; and
in the same row of isolation openings, the third contour lines of the first isolation openings, the third contour lines of the second isolation openings and the third contour lines of the third isolation openings are flush, and the fourth contour lines of the first isolation openings, the fourth contour lines of the second isolation openings and the fourth contour lines of the third isolation openings are flush.

5. The display panel according to claim 2, wherein the columns of isolation openings comprise a first column of isolation openings, a second column of isolation openings and a third column of isolation openings that are adjacent to each other, and the isolation openings comprise first isolation openings, second isolation openings and third isolation openings;
a plurality of first isolation openings are distributed in the first direction to form the first column of isolation openings, a plurality of second isolation openings are distributed in the first direction to form the second column of isolation openings, and a plurality of third isolation openings are distributed in the first direction to form the third column of isolation openings;
one first isolation opening, one second isolation opening and one third isolation opening form an isolation opening unit, and a plurality of isolation opening units are arranged in the second direction to form the row of isolation openings; and
in the same row of isolation openings, the third contour lines of the first isolation openings, the third contour lines of the second isolation openings and the third contour lines of the third isolation openings are flush, and the fourth contour lines of the first isolation openings, the fourth contour lines of the second isolation openings and the fourth contour lines of the third isolation openings are flush.

6. The display panel according to claim 2, wherein the columns of isolation openings comprise a first column of isolation openings and a second column of isolation openings that are adjacent to each other, and the isolation openings comprise first isolation openings, second isolation openings, and third isolation openings;
the first isolation openings and the second isolation openings are arranged alternately in the first direction to form the first column of isolation openings;
a plurality of third isolation openings are arranged in the first direction to form the second column of isolation openings;
one first isolation opening, one second isolation opening and one third isolation opening form an isolation opening unit, and a plurality of isolation opening units are arranged in the second direction to form the row of isolation openings; and in the same row of isolation openings, the third contour lines of the first isolation openings and the third contour lines of the third isolation openings are flush, and the fourth contour lines of the second isolation openings and the fourth contour lines of the third isolation openings are flush.

7. The display panel according to claim 2, wherein in the same column of isolation openings, the orthographic projections of different isolation openings on the substrate have the same shape and area size; and
the orthographic projections of the isolation openings in different columns of isolation openings on the substrate have the same or similar shape, and the orthographic projections of the isolation openings in different columns of isolation openings on the substrate have the same or different area size.

8. The display panel according to claim 4, wherein
a contour line of an orthographic projection of each encapsulation unit on the substrate comprises a fifth contour line extending in the first direction and located on a side of the encapsulation unit and a sixth contour line located on a side opposite the side where the fifth contour line is located and extending in the first direction; and
the fifth contour lines of different encapsulation units for encapsulating the light-emitting devices in different isolation openings in the same column of isolation openings are flush, and the sixth contour lines of different encapsulation units for encapsulating the light-emitting devices in different isolation openings in the same column of isolation openings are flush.

9. The display panel according to claim 8, wherein the contour line of the orthographic projection of the encapsulation unit on the substrate comprises a seventh contour line extending in the second direction and located on a side of the encapsulation unit and an eighth contour line located on a side opposite the side where the seventh contour line is located and extending in the second direction;
the encapsulation units include first encapsulation units, second encapsulation units and third encapsulation units, the first encapsulation units being used for encapsulating the light-emitting devices in the first isolation openings, the second encapsulation units being used for encapsulating the light-emitting devices in the second isolation openings, and the third encapsulation units being used for encapsulating the light-emitting devices in the third isolation openings;
two adjacent encapsulation units for encapsulating the light-emitting devices are disconnected on a side of the isolation structure away from the substrate; and
the seventh contour lines of the encapsulation units for encapsulating the light-emitting devices in different isolation openings in the same row of isolation openings are flush, and the eighth contour lines of the encapsulation units for encapsulating the light-emitting devices in different isolation openings in the same row of isolation openings are flush; or
the seventh contour lines of the first encapsulation units and the third encapsulation units for encapsulating the light-emitting devices in different isolation openings in the same row of isolation openings are flush, and the eighth contour lines of the second encapsulation units and the third encapsulation units for encapsulating the light-emitting devices in different isolation openings in the same row of isolation openings are flush.

10. The display panel according to claim 9, wherein
a distance between the fifth contour lines of adjacent encapsulation units for encapsulating the light-emitting devices in different isolation openings in the same column of isolation openings in the second direction is less than or equal to 3 μm, and a distance between the sixth contour lines of adjacent encapsulation units for encapsulating the light-emitting devices in different isolation openings in the same column of isolation openings in the second direction is less than or equal to 3 μm; and
a distance between the seventh contour lines of adjacent encapsulation units for encapsulating the light-emitting devices in different isolation openings in the same row of isolation openings in the first direction is less than or equal to 3 μm, and a distance between the eighth contour lines of adjacent encapsulation units for encapsulating the light-emitting devices in different isolation openings in the same row of isolation openings in the first direction is less than or equal to 3 μm; or
a distance between the seventh contour lines of the first encapsulation units and the third encapsulation units for encapsulating the light-emitting devices in different isolation openings in the same row of isolation openings in the first direction is less than or equal to 3 μm, and a distance between the eighth contour lines of the second encapsulation units and the third encapsulation units for encapsulating the light-emitting devices in different isolation openings in the same row of isolation openings in the first direction is less than or equal to 3 μm.

11. The display panel according to claim 8, wherein in a direction away from the substrate, each light-emitting device comprises a first electrode, a light-emitting material layer and a second electrode that are stacked, the first electrode being located on a side of the isolation structure facing the substrate, and the second electrode lapping with the isolation structure; and
the light-emitting devices comprise first light-emitting devices, second light-emitting devices and third light-emitting devices of different luminous colors, wherein at least part of the first light-emitting devices are located in the first isolation openings, at least part of the second light-emitting devices are located in the second isolation openings and at least part of the third light-emitting devices are located in the third isolation openings.

12. The display panel according to claim 11, wherein an orthographic projection of the first electrode on the substrate at least partially overlaps the orthographic projection of the isolation opening on the substrate;
a plurality of first electrodes are arrayed in a plurality of columns of first electrodes arranged in the second direction;
a contour line of the orthographic projection of the first electrode on the substrate comprises a ninth contour line extending in the first direction and located on a side of the first electrode and a tenth contour line located on a side opposite the side where the ninth contour line is located and extending in the first direction; and
in the same column of first electrodes, the ninth contour lines of different first electrodes are flush and the tenth contour lines of different first electrodes are flush.

13. The display panel according to claim 12, wherein the plurality of first electrodes are also arrayed in a plurality of rows of first electrodes arranged in the first direction;
the contour line of the orthographic projection of the first electrode on the substrate comprises an eleventh contour line extending in the second direction and located on a side of the first electrode and a twelfth contour line located on a side opposite the side where the eleventh contour line is located and extending in the second direction, wherein the first electrodes comprise first sub-electrodes, second sub-electrodes and third sub-electrodes, and wherein an orthographic projection of each first sub-electrode on the substrate at least partially overlaps an orthographic projection of each first isolation opening on the substrate, an orthographic projection of each second sub-electrode on the substrate at least partially overlaps an orthographic projection of each second isolation opening on the substrate, and an orthographic projection of each third sub-electrode on the substrate at least partially overlaps an orthographic projection of each third isolation opening on the substrate; and
in the same row of first electrodes, the eleventh contour lines of different first electrodes are flush and the twelfth contour lines of different first electrodes are flush; or
in the same row of first electrodes, the eleventh contour lines of the first sub-electrodes and the eleventh contour lines of the third sub-electrodes are flush and the twelfth contour lines of the second sub-electrodes and the twelfth contour lines of the third sub-electrodes are flush.

14. The display panel according to claim 13, wherein
in the same column of first electrodes, a distance between a point on the ninth contour line of the first electrode and a point on the ninth contour line of an adjacent first electrode in the second direction is less than or equal to 3 μm, and a distance between a point on the tenth contour line of the first electrode and a point on the tenth contour line of an adjacent first electrode in the second direction is less than or equal to 3 μm; and
in the same row of first electrodes, a distance between a point on the eleventh contour line of the first electrode and a point on the eleventh contour line of an adjacent first electrode in the first direction is less than or equal to 3 μm, and a distance between a point on the twelfth contour line of the first electrode and a point on the twelfth contour line of an adjacent isolation opening in the first direction is less than or equal to 3 μm; or
in the same row of first electrodes, a distance between a point on the eleventh contour line of the first sub-electrode and a point on the eleventh contour line of an adjacent third sub-electrode in the first direction is less than or equal to 3 μm, and a distance between a point on the twelfth contour line of the second sub-electrode and a point on the twelfth contour line of an adjacent third sub-electrode in the first direction is less than or equal to 3 μm.

15. The display panel according to claim 11, further comprising a pixel defining layer located on a side of the substrate, wherein the isolation structure is located on a side of the pixel defining layer away from the substrate;
the first electrodes are located on a side of the pixel defining layer facing the substrate, the pixel defining layer is provided with a plurality of pixel openings, the pixel openings are in communication with the isolation openings, and the first electrodes are at least partially exposed from the pixel openings;
the plurality of pixel openings are arrayed in a plurality of rows of pixel openings arranged in the first direction;
a contour line of an orthographic projection of each pixel opening on the substrate comprises a fifteenth contour line extending in the second direction and located on a side of the pixel opening and a sixteenth contour line located on a side opposite the side where the fifteenth contour line is located and extending in the second direction; and
in the same row of pixel openings, the fifteenth contour lines of at least part of the pixel openings are flush and the sixteenth contour lines of at least part of the pixel openings are flush.

16. The display panel according to claim 15, wherein the plurality of the pixel openings are also arrayed in a plurality of columns of pixel openings arranged in the second direction;
the contour line of the orthographic projection of the pixel opening on the substrate comprises a thirteenth contour line extending in the first direction and located on a side of the pixel opening and a fourteenth contour line located on a side opposite the side where the thirteenth contour line is located and extending in the first direction, and the pixel openings comprise first pixel openings, second pixel openings and third pixel openings, the first pixel openings being in communication with the first isolation openings, the second pixel openings being in communication with the second isolation openings, and the third pixel openings being in communication with the third isolation openings; and
in the same column of pixel openings, the thirteenth contour lines of the same pixel openings are flush and the fourteenth contour lines of the same pixel openings are flush.

17. The display panel according to claim 16, wherein
in the same column of pixel openings, a distance between the thirteenth contour lines of at least part of adjacent pixel openings in the second direction is less than or equal to 3 μm, and a distance between the fourteenth contour lines of at least part of adjacent pixel openings in the second direction is less than or equal to 3 μm;
in the same row of pixel openings, a distance between the fifteenth contour lines of the same pixel openings in the first direction is less than or equal to 3 μm, and a distance between the sixteenth contour lines of the same pixel openings in the first direction is less than or equal to 3 μm; and
in the same row of pixel openings, a distance between the fifteenth contour lines of different pixel openings in the first direction is greater than 3 μm, or a distance between the sixteenth contour lines of different pixel openings in the second direction is greater than 3 μm.

18. A display panel, comprising:
a substrate;
an isolation structure located on the substrate and comprising a plurality of isolation openings, the plurality of isolation openings being arrayed in a plurality of columns of isolation openings arranged in a second direction;
light-emitting devices, at least part of the light-emitting devices being located in the isolation openings; and
encapsulation units for encapsulating the light-emitting devices in the isolation openings, wherein a contour line of an orthographic projection of each encapsulation unit on the substrate comprises a fifth contour line extending in a first direction and located on a side of the encapsulation unit and a sixth contour line located on a side opposite the side where the fifth contour line is located and extending in the first direction, the first direction intersecting the second direction; and
the fifth contour lines of different encapsulation units for encapsulating the light-emitting devices in different isolation openings in the same column of isolation openings are flush, and the sixth contour lines of different encapsulation units for encapsulating the light-emitting devices in different isolation openings in the same column of isolation openings are flush.

19. The display panel according to claim 18, wherein a contour line of an orthographic projection of each isolation opening on the substrate comprises a first contour line extending in the first direction and located on a side of the isolation opening and a second contour line located on a side opposite the side where the first contour line is located and extending in the first direction; and
in the same column of isolation openings, the first contour lines of different isolation openings are flush, the second contour lines of different isolation openings are flush.

20. An electronic device, comprising:
a display panel, comprising:
a substrate;
an isolation structure located on the substrate and comprising a plurality of isolation openings, the plurality of isolation openings being arrayed in a plurality of columns of isolation openings arranged in a second direction, wherein
a contour line of an orthographic projection of each isolation opening on the substrate comprises a first contour line extending in a first direction and located on a side of the isolation opening and a second contour line located on a side opposite the side where the first contour line is located and extending in the first direction; and in the same column of isolation openings, the first contour lines of different isolation openings are flush, and the second contour lines of different isolation openings are flush, the first direction intersecting the second direction;
light-emitting devices, at least part of the light-emitting devices being located in the isolation openings; and
encapsulation units for encapsulating the light-emitting devices in the isolation openings.
